(19) United States
(12) Patent Application Publication
(10) Pub. No.: US 2025/0057021 A1
(43) Pub. Date: Feb. 13, 2025

(54) DISPLAY PANEL AND DISPLAY DEVICE

(71) Applicant: KunShan Go-Visionox Opto-Electronics Co., Ltd, Kunshan (CN)

(72) Inventors: Wei LI, Kunshan (CN); Won jun SONG, Kunshan (CN); Mihwa HA, Kunshan (CN); Junzhe LIU, Kunshan (CN); Chufang MA, Kunshan (CN)

(73) Assignee: KunShan Go-Visionox Opto-Electronics Co., Ltd, Kunshan (CN)

(21) Appl. No.: 18/932,974

(22) Filed: Oct. 31, 2024

(30) Foreign Application Priority Data
Nov. 27, 2023 (CN) 202311589879.3

(51) Int. Cl. H10K 59/80; H10K 102/00

(52) U.S. Cl. CPC H10K 59/879; H10K 59/873; H10K 2102/351

(57) ABSTRACT

A display panel and a display device. The display panel includes a substrate, a light-emitting layer and a light adjusting layer. The light-emitting layer includes a plurality of light-emitting units formed on a side of the substrate. The light adjusting layer is arranged on a side of the light-emitting layer away from the substrate and includes a first adjusting layer and a second adjusting layer, the first adjusting layer and the second adjusting layer are alternately stacked along a direction away from the substrate, a refractive index of the first adjusting layer is less than a refractive index of the second adjusting layer, and the first adjusting layer is arranged on each of an end of the light adjusting layer close to the substrate and an end of the light adjusting layer away from the substrate.

### CROSS REFERENCE

The present disclosure claims priority to Chinese Patent Application No. 202311589879.3 titled “DISPLAY PANEL AND DISPLAY DEVICE” filed on Nov. 27, 2023, which is incorporated herein by reference in its entirety.

### TECHNICAL FIELD

The present disclosure relates to the technical field of display, in particular to a display panel and a display device.

### BACKGROUND

With a rapid development of science and technology, display media has become an important part in people's lives. The display media of organic light emitting diode (OLED) exhibits excellent color and picture quality due to their self-luminescence.

With a continuous development of an OLED display panel, customers' requirement on power consumption is becoming higher and higher. At present, the power consumption of the OLED display panel is high, which fails to meet the requirement.

### SUMMARY

The present embodiment provides a display panel and a display device, which can reduce power consumption and achieve low power consumption.

Embodiments of the present in a first aspect disclosure provides a display panel, including:
a substrate;
a light-emitting layer comprising a plurality of light-emitting units formed on a side of the substrate; and
a light adjusting layer arranged on a side of the light-emitting layer away from the substrate and comprising a first adjusting layer and a second adjusting layer, the first adjusting layer and the second adjusting layer being alternately stacked along a direction away from the substrate, a refractive index of the first adjusting layer being less than a refractive index of the second adjusting layer, and the first adjusting layer being arranged on each of an end of the light adjusting layer close to the substrate and an end of the light adjusting layer away from the substrate.

According to embodiments of the present disclosure in the first aspect, an orthographic projection of the light adjusting layer on the substrate covers the substrate, the first adjusting layer is continuous in a direction parallel to the substrate, and the second adjusting layer is continuous in the direction parallel to the substrate.

According to embodiments of the present disclosure in the first aspect, two first adjusting layers are provided, the two first adjusting layers are configured as a first sub-adjusting layer and a second sub-adjusting layer arranged in a direction away from the substrate respectively, and one second adjusting layer is provided and located between the first sub-adjusting layer and the second sub-adjusting layer;
preferably, the display panel further includes an encapsulation layer, and the encapsulation layer is located on a side of the light adjusting layer away from the substrate and is in contact with the light adjusting layer;
a thickness of the second adjusting layer is defined as a first fixed value;
a thickness of the first sub-adjusting layer is D1, and a refractive index of the first sub-adjusting layer is N1, wherein D1=P1*N1+Q1, 0≤P1≤100 and −120≤Q1≤221 are satisfied;
a thickness of the second sub-adjusting layer is D2, and a refractive index of the second sub-adjusting layer is N2, wherein D2=P2*N2+Q2, −100≤P2≤0 and −60≤Q2≤251 are satisfied;
or,
an optical film layer and an encapsulation layer are provided, the optical film layer is located on a side of the light adjusting layer away from the substrate and is in contact with the light adjusting layer, and the encapsulation layer is located on a side of the optical film layer away from the substrate;
a thickness of the second adjusting layer is defined as a first fixed value;
a thickness of the first sub-adjusting layer is D1, and an refractive index of the first sub-adjusting layer is N1, wherein D1=P1*N1+Q1, 0≤P1≤100 and −120≤Q1≤221 are satisfied;
a thickness of the second sub-adjusting layer is D2, and a refractive index of the second sub-adjusting layer is N2, wherein D2=P2*N2+Q2, −100≤P2≤0 and 170≤Q2≤221 are satisfied; and
preferably, the first fixed value is 65 nm.

According to embodiments of the present disclosure in the first aspect, the light adjusting layer includes a plurality of light adjusting portions arranged to be spaced apart from each other, the light adjusting portions are located on sides of light-emitting units away from the substrate, and each light adjusting portion is correspondingly arranged for one light emitting unit in one color; and
preferably, two first adjusting layers are provided and configured as a first sub-adjusting layer and a second sub-adjusting layer arranged in a direction away from the substrate, one second adjusting layer is provided, and the second adjusting layer is located between the first sub-adjusting layer and the second sub-adjusting layer.

According to embodiments of the present disclosure in the first aspect, an encapsulation layer is further provided, wherein the encapsulation layer is located on a side of the light adjusting layer away from the substrate and is in contact with the light adjusting layer;
a thickness of the second adjusting layer is defined as a first fixed value;
a thickness of the first sub-adjusting layer is positively correlated with a refractive index of the first sub-adjusting layer, and a thickness of the first sub-adjusting layer is D1, wherein 15 nm≤D1≤40 nm is satisfied;
a thickness of the second sub-adjusting layer is D2, and a wavelength of a light emitted by the light-emitting unit opposite to the second sub-adjusting layer along a thickness direction of the substrate is W, wherein D2=M*W²+V*W+S, −0.009≤M≤−0.003, 3.7≤V≤9.0 and −2240≤S≤−740 are satisfied;
preferably, the first fixed value is 65 nm;
or,
wherein the display panel further includes an optical film layer and an encapsulation layer, the optical film layer is located on a side of the light adjusting layer away from the substrate and is in contact with the light adjusting layer, and the encapsulation layer is located on a side of the optical film layer away from the substrate;
a thickness of the second adjusting layer is defined as a first fixed value;
a thickness of the first sub-adjusting layer is positively correlated with a refractive index of the first sub-adjusting layer, and a thickness of the first sub-adjusting layer is D1, wherein 15 nm 15 nm≤D1≤40 nm is satisfied;
a thickness of the second sub-adjusting layer is D2, and a wavelength of a light emitted by the light-emitting unit opposite to the second sub-adjusting layer along a thickness direction of the substrate is W, wherein D2=M*W²+V*W+S, −0.009≤M≤−0.003, 3.7≤V≤9.0 and −2300≤S≤−800 are satisfied; and
preferably, the first fixed value is 65 nm.

According to embodiments of the present disclosure in the first aspect, the plurality of light-emitting units include a first light-emitting unit, a second light-emitting unit and a third light-emitting unit, a wavelength of a light emitted by the first light-emitting unit is 460 nm, a wavelength of a light emitted by the second light-emitting unit is 530 nm, and a wavelength of a light emitted by the third light-emitting unit is 620 nm;
the plurality of light adjusting portions include a first light adjusting portion, a second light adjusting portion and a third light adjusting portion arranged to be spaced apart from each other, the first light adjusting portion is located on a side of the first light-emitting unit away from the substrate, the second light adjusting portion is located on a side of the second light-emitting unit away from the substrate, and the third light adjusting portion is located on a side of the third light-emitting unit away from the substrate;
preferably, an encapsulation layer is provided, which is located on a side of the light adjusting layer away from the substrate and is in contact with the light adjusting layer;
a thickness of the second adjusting layer is defined as a first fixed value;
a thickness of the first sub-adjusting layer is D1, and a refractive index of the first sub-adjusting layer is N1, a thickness of the second sub-adjusting layer is D2, and a refractive index of the second sub-adjusting layer is N2;
for a part of the first sub-adjusting layer located within the first light adjusting portion, D1=100*N1−119 is satisfied, and for a part of the second sub-adjusting layer located within the first light adjusting portion, D2=−100*N2+281 is satisfied;
for a part of the first sub-adjusting layer located within the second light adjusting portion: D1=100*N1−119 is satisfied, and for a part of the second sub-adjusting layer located within the second light adjusting portion: D2=(2*e⁻¹²) N2+161 is satisfied;
for a part of the first sub-adjusting layer located within the third light adjusting portion: D1=100*N1−119 is satisfied, and for a part of the second sub-adjusting layer located within the third light adjusting portion: D2=−100*N2+131 is satisfied;
or,
the display panel further includes an optical film layer and an encapsulation layer, the optical film layer is located on a side of the light adjusting layer away from the substrate and is in contact with the light adjusting layer, and the encapsulation layer is located on a side of the optical film layer away from the substrate;
a thickness of the second adjusting layer is defined as a first fixed value;
a thickness of the first sub-adjusting layer is D1, and refractive index of the first sub-adjusting layer is N1, and a refractive index of the second sub-adjusting layer is N2;
for a part of the first sub-adjusting layer located within the first light adjusting portion, D1=100*N1−119 is satisfied, and for a part of the second sub-adjusting layer located within the first light adjusting portion, D2=−100*N2+221 is satisfied;
for a part of the first sub-adjusting layer located within the second light adjusting portion, D1=100*N1−119 is satisfied, and for a part of the second sub-adjusting layer located within the second light adjusting portion, D2=(2*e⁻¹²) N2+101 is satisfied; and
for a part of the first sub-adjusting layer located within the third light adjusting portion, D1=100*N1−119 is satisfied, for a part of the second sub-adjusting layer located within the third light adjusting portion, D2=−100*N2+191 is satisfied, and preferably, the first fixed value is 65 nm.

According to embodiments of the present disclosure in the first aspect, the display panel further includes an encapsulation layer, the encapsulation layer is located on a side of the light adjusting layer away from the substrate and is in contact with the light adjusting layer, and a thickness of the light adjusting layer is D, wherein 120 nm≤D≤260 nm is satisfied;
or,
the display panel further includes an optical film layer and an encapsulation layer, the optical film layer is located on a side of the light adjusting layer away from the substrate and is in contact with the light adjusting layer, the encapsulation layer is located on a side of the optical film layer away from the substrate, and a thickness of the light adjusting layer is D, wherein 60 nm≤D≤200 nm is satisfied.

According to embodiments of the present disclosure in the first aspect, the first adjusting layer is in a structure of multiple layers, and refractive indices of at least some of the layers are different and are all smaller than the refractive index of the second adjusting layer;
and/or,
the second adjusting layer is in a structure of multiple layers, and refractive indices of at least some of the layers are different and all are greater than the refractive index of the first adjusting layer;
preferably, a material of the first adjusting layer includes a fluorine-containing organic compound, a polymer or a metal oxide; a material of the second adjusting layer include fluorenes, spirofluorenes, or diazinecans;
preferably, a material of the first adjusting layer includes an organic material; and
preferably, a material of the first adjusting layer includes molybdenum oxide or silicon dioxide.

According to embodiments of the present disclosure in the first aspect, the refractive index of the first adjusting layer is N3, wherein 2.1≤N3≤2.2 is satisfied; and the refractive index of the second adjusting layer is N4, wherein 1.5≤N4≤1.6 is satisfied.

Embodiments of the present in a second aspect disclosure provides a display device comprising the display panel provided in the first aspect.

The display panel provided in the present disclosure includes the substrate, the light-emitting layer and the light adjusting layer. The light-emitting layer includes the plurality of light-emitting units for display. The light adjusting layer is arranged on a side of the light-emitting layer away from the substrate and configured for adjusting the light emitted by the light-emitting units; the light adjusting layer includes the first adjusting layer and the second adjusting layer, the first adjusting layer and the second adjusting layer are alternately stacked along a direction away from the substrate, a refractive index of the first adjusting layer is less than an refractive index of the second adjusting layer, and the first adjusting layer is arranged on each of an end of the light adjusting layer close to the substrate and an end of the light adjusting layer away from the substrate. The first adjusting layer is directly in contact with the light-emitting units, i.e. the first adjusting layer is located between the second adjusting layer and the light-emitting units, which can reduce resonance of photons between the light-emitting units and the second adjusting layer, thereby reducing photon traps and coupling between photons and electrons inside the light-emitting units and thus reducing power consumption. At the same time, the combination of the first adjusting layer and an adjacent second adjusting layer can achieve convergence of the light with a large angle emitted by the light-emitting units, thereby improving a light output efficiency and further reducing power consumption. With the first adjusting layer at the end of the light adjusting layer away from the substrate, the refractive index difference between the second adjusting layer located on the side of the first adjusting layer close to the substrate and a film layer on a side of the first adjusting layer away from the substrate can be reduced, thereby reducing light loss caused by total reflection and thus improving a light output to further reduce power consumption.

### BRIEF DESCRIPTION OF THE DRAWINGS

In order to provide a clearer explanation of technical solutions in embodiments of the present disclosure, a brief introduction will be made to accompanying drawings required in embodiments of the present disclosure. It is evident that the accompanying drawings described below are only some of embodiments of the present disclosure, and for those skilled in the art, other accompanying drawings can be obtained based on these drawings without creative labor.

FIG. 1 is a schematic structural diagram of a display panel provided in embodiments of the present disclosure;

FIG. 2 is a sectional view along E-E′ in FIG. 1;

FIG. 3 is another sectional view along a line E-E′ in FIG. 1; FIG. 4 is another sectional view along the line E-E′ in FIG. 1;

FIG. 5 is another sectional view along the line E-E′ in FIG. 1; FIG. 6 is another sectional view along the line E-E′ in FIG. 1; FIG. 7 is another sectional view along the line E-E′ in FIG. 1;

FIG. 8 is another sectional view along E-E′ in FIG. 1; FIG. 9 is a schematic structural diagram of t a display device provided in embodiments of the present disclosure.

### IN DRAWINGS

1. Display panel; 10—Substrate; 11—Light-emitting layer; 110—Light-emitting unit; 111—First electrode; 112—Light-emitting functional layer; 113—Second electrode; 12—Light adjusting layer; 121—First adjusting layer; 120—Light adjusting portion; 1211—First sub-adjusting layer; 1212—Second sub-adjusting layer; 122—Second adjusting layer; 13—Optical film layer; 14—Encapsulation layer; 141—First encapsulation layer; 142—Second encapsulation layer; 143—Third encapsulation layer; 2—Display device.

### DETAILED DESCRIPTION

A detailed description of features and exemplary embodiments of various aspects of the present disclosure will be provided below. In the detailed description below, many specific details are presented to provide a comprehensive understanding of the present disclosure. However, it is evident to those skilled in the art that the present disclosure can be implemented without some of these specific details. The following description of embodiments is only intended to provide a better understanding of the present disclosure by illustrating examples of the present disclosure.

It should be noted that in the text, relational terms, such as first and second, are only used to distinguish one entity or operation from another entity or operation, and do not necessarily require or imply any actual relationship or order between these entities or operations. Moreover, the terms “include”, “comprise”, or any other variation thereof are intended to encompass non-exclusive inclusion, such that a process, method, item, or device that includes a series of elements not only includes these elements, but also includes other elements that are not explicitly listed, or also includes elements inherent to such process, method, item, or device. Without further limitations, the elements limited by the statement “including . . . ” do not exclude the existence of other identical elements in the process, method, item, or device that includes the elements.

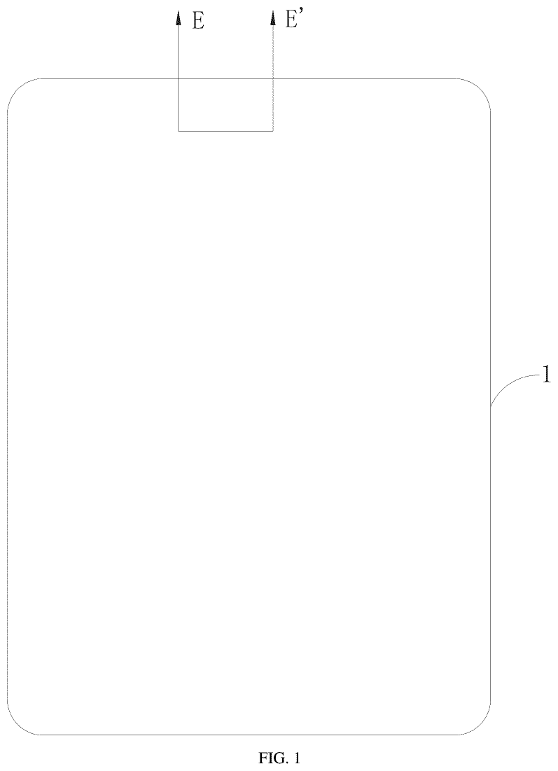

In order to better understand the present disclosure, a detailed description of a display panel and display device according to embodiments of the present disclosure will be provided below combined with FIGS. 1 to 9.

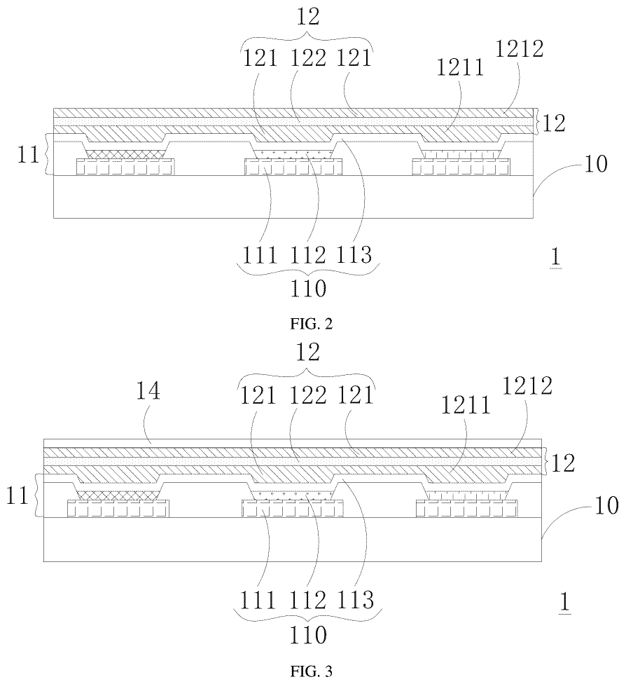

Referring to FIGS. 1 and 2, embodiments of the present disclosure provide a display panel, including: a substrate 10, a light-emitting layer 11 and a light adjusting layer 12. The light-emitting layer 11 includes a plurality of light-emitting units 110 formed on a side of the substrate 10. The light adjusting layer 12 is arranged on a side of the light-emitting layer 11 away from the substrate 10 and includes a first adjusting layer 121 and a second adjusting layer 122. The first adjusting layer 121 and the second adjusting layer 122 are alternately stacked along a direction away from the substrate 10. A refractive index of the first adjusting layer 121 is less than a refractive index of the second adjusting layer 122, and the first adjusting layer 121 is arranged on each of an end of the light adjusting layer 12 close to the substrate 10 and an end of the light adjusting layer 12 away from the substrate 10.

The display panel 1 provided in the present disclosure includes the substrate 10, the light-emitting layer 11 and the light adjusting layer 12. The light-emitting layer 11 includes the plurality of light-emitting units 110 for display. The light adjusting layer 12 is arranged on a side of the light-emitting layer 11 away from the substrate 10 and configured for adjusting the light emitted by the light-emitting units 110; the light adjusting layer 12 includes the first adjusting layer 121 and the second adjusting layer 122, the first adjusting layer 121 and the second adjusting layer 122 are alternately stacked along a direction away from the substrate 10, a refractive index of the first adjusting layer 121 is less than an refractive index of the second adjusting layer 122, and the first adjusting layer 121 is arranged on each of an end of the light adjusting layer 12 close to the substrate 10 and an end of the light adjusting layer 12 away from the substrate 10. One first adjusting layer 121 is directly in contact with the light-emitting units 110, i.e. the first adjusting layer 121 is located between the second adjusting layer 122 and the light-emitting units 110, which can reduce resonance of photons between the light-emitting units 110 and the second adjusting layer 122, thereby reducing photon traps and coupling between photons and electrons inside the light-emitting units 110 and thus reducing power consumption. At the same time, the combination of the first adjusting layer 121 and an adjacent second adjusting layer 122 can achieve convergence of the light with a large angle emitted by the light-emitting units 110, thereby improving a light output efficiency and further reducing power consumption. With the first adjusting layer 121 at the end of the light adjusting layer 12 away from the substrate 10, a refractive index difference between the second adjusting layer 122 located on the side of the first adjusting layer 121 close to the substrate 10 and a film layer on a side of the first adjusting layer 121 away from the substrate 10 can be reduced, thereby reducing light loss caused by total reflection and thus improving a light output to further reduce power consumption.

In the above embodiments, a thickness refers to a size along a direction perpendicular to the plane where the substrate 10 is located, which can be the maximum size along the direction perpendicular to the plane where the substrate 10 is located.

Each light-emitting unit 110 may include a first electrode 111, a light-emitting functional layer 112, and a second electrode 113 stacked in the direction away from the substrate 10. The first adjusting layer 121 is provided between the second electrode 113 and the second adjusting layer 122 to reduce the consumption generated by coupling of photonics and electron between the second electrode 113 and the second adjusting layer 122, thereby reducing power consumption.

In a feasible embodiment, as shown in FIG. 2, an orthographic projection of the light adjusting layer 12 on the substrate 10 covers the substrate 10, the first adjusting layer 121 is continuous in a direction parallel to the substrate 10, and the second adjusting layer 122 is continuous in a direction parallel to the substrate 10.

In the above embodiment, the light adjusting layer 12 is of a film layer in a whole layer, that is, the whole layer is arranged in a plane. The orthographic projection of the light adjusting layer 12 on the substrate 10 covers the substrate 10, which can simplify a preparation process of the light adjusting layer 12 and reduce a preparation cost, and provide a flat surface for the preparation of a subsequent film layer to improve a yield of the subsequent film layer.

In a feasible embodiment, the total number of the first adjusting layer 121 and the second adjusting layer 122 within the light adjusting layer 12 is 2n+1, wherein n>0 and n is an integer.

In a feasible embodiment, as shown in FIG. 2, the total number of the first adjusting layer 121 and the second adjusting layer 122 in the light adjusting layer 12 is 3, and the number of film layers is relatively small, and the first adjusting layer 121 is provided at each of the end of the light adjusting layer 12 close to the substrate 10 and the end of the light adjusting layer 12 away from the substrate 10, thereby simplifying the preparation process.

Specifically, two first adjusting layers 121 are provided. The two first adjusting layers 121 are formed as the first sub-adjusting layer 1211 and the second sub-adjusting layer 1212 arranged in a direction away from the substrate 10. One second adjusting layer 122 is provided, and the second adjusting layer 122 is located between the first sub-adjusting layer 1211 and the second sub-adjusting layer 1212.

In the above embodiment, the first sub-adjusting layer 1211 is formed as one first adjusting layer 121, and the second sub-adjusting layer 1212 is formed as one first adjusting layer 121. The refractive indices of the first sub-adjusting layer 1211 and the second sub-adjusting layer 1212 are both lower than the refractive index of the second adjusting layer 122.

The first sub-adjusting layer 1211 is located on the side of the second adjusting layer 122 towards the substrate 10, and the second sub-adjusting layer 1212 is located on the side of the second adjusting layer 122 away from the substrate 10. The first sub-adjusting layer 1211 is in contact with the light-emitting units 110, thereby reducing the resonance of the photon between the light-emitting units 110 and the second adjusting layer 122 to reduce the photon trap, reducing the coupling between the photon and the electrons in the light-emitting units 110, and thus reducing the power consumption. The first sub-adjusting layer 1211 is combined with the second adjusting layer 122. Since the refractive index of the first sub-adjusting layer 1211 is smaller than that of the second sub-adjusting layer 1212, the light in a large angle emitted by the light-emitting unit 110 can be converged, so as to improve the optical efficiency and further reduce the power consumption while ensuring an optical angle of view. The second sub-adjusting layer 1212 can reduce a refractive index difference between the second adjusting layer 122 and the film layer at a side of the second sub-regulator layer 1212 away from the substrate 10, so as to reduce the light loss caused by total reflection, thereby increasing the light output efficiency to further reduce the power consumption.

In a feasible embodiment, as shown in FIG. 3, the display panel 1 also includes an encapsulation layer 14, which is located on a side of the light adjusting layer 12 away from the substrate 10 and in contact with the light adjusting layer 12. The encapsulation layer 14 plays the role of isolating water and oxygen, which can protect the light emitting unit 110 to improve the yield of the light emitting unit 110.

In this case, a thickness of the second adjusting layer 122 can be a first fixed value. Specifically, the first fixed value is 65 nm. The thickness can be applied to a full-band adjustment of a light output of the light emitting unit 110.

A thickness of the first sub-adjusting layer 1211 is D1, and a refractive index of the first sub-adjusting layer 1211 is N1, wherein D1=P1*N1+Q1, 0≤P1≤100 and −120≤Q1≤221 are satisfied. A thickness of the second sub-adjusting layer 1212 is D2, and a refractive index of the second sub-adjusting layer 1212 is N2, wherein D2=P2*N2+Q2, −100≤P2≤0 and −60≤Q2≤251 are satisfied.

In the above embodiment, the thickness of the first sub-adjusting layer 1211 can be set according to the refractive index of the first sub-adjusting layer 1211, and the thickness of the second sub-adjusting layer 1212 can be set according to the refractive index of the second sub-adjusting layer 1212. Thus, a good light adjusting effect can be achieved.

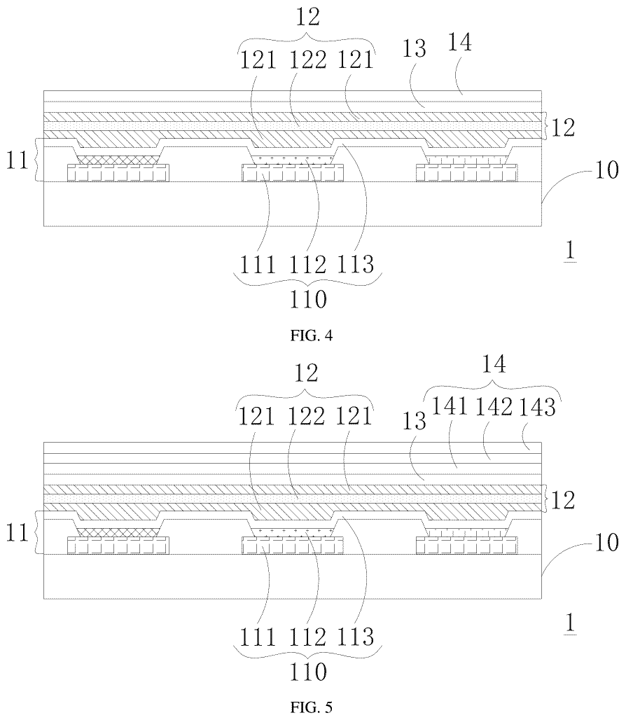

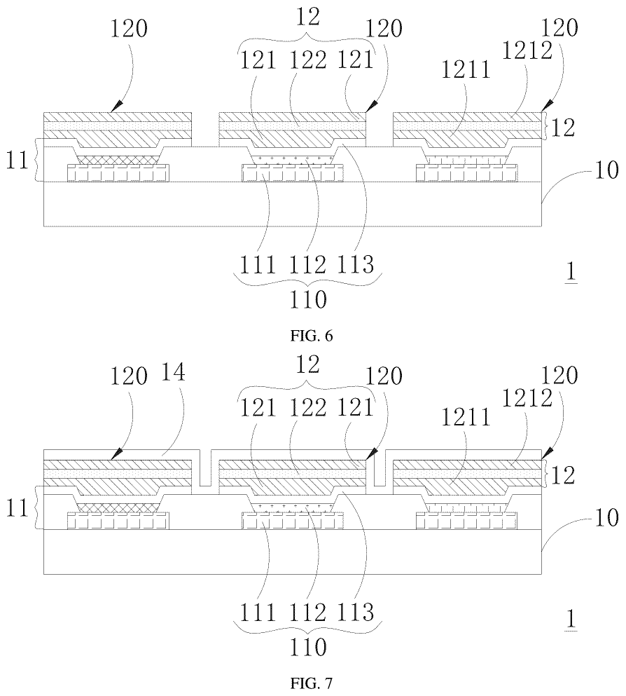

In a feasible embodiment, as shown in FIGS. 4 and 5, the display panel 1 also includes an optical film layer 13 and an encapsulation layer 14, with the optical film layer 13 located on the side of the light adjusting layer away from the substrate 10 and in contact with the light adjusting layer, and the encapsulation layer 14 located on the side of the optical film layer 13 away from the substrate 10.

The encapsulation layer 14 may include a first encapsulation layer 141, a second encapsulation layer 142 and a third encapsulation layer 143 stacked in a direction away from the substrate 10. Materials of the first encapsulation layer 141 and the third encapsulation layer 143 may include inorganic materials, and materials of the second encapsulation layer 142 may include organic materials. The inorganic materials have a stronger ability to insulate water and oxygen than the organic materials, to provide a good sealing effect. The ductility and flatness of the organic materials are stronger than the inorganic materials, which can provide a flat surface for the third encapsulation layer 143, and improve the flatness and yield of the third encapsulation layer 143 to improve the encapsulating effect.

The refractive index of the first encapsulation layer 141 can be higher than that of the second sub-adjusting layer 1212. The refractive index of the first encapsulation layer 141 can be higher than that of the optical film layer 13, and the refractive index of the optical film layer 13 is lower than that of the second sub-adjusting layer 1212.

Specifically, materials of the optical film layer 13 can be inorganic materials, which are more stable, and particularly can be lithium fluoride.

In the above embodiment, the refractive index of the optical film layer 13 is lower than the refractive index of the first encapsulation layer 141, to converge the light emitted by the light emitting unit 110, thereby increasing the light output efficiency of the display panel 1, thereby reducing the power consumption.

In the above embodiment, one optical film layer 13 is added between the encapsulation layer 14 and the light adjusting layer, and the refractive index of the optical film layer 13 is lower than that of the second sub-adjusting layer 1212, thereby further reducing the refractive index difference between the encapsulation layer 14 and a lower film layer to improve the convergence of light emitted by the light emitting unit 110, and thus further increasing the light output rate and reducing the power consumption.

At this time, a thickness of a second adjusting layer 122 is a first fixed value. Specifically, the first fixed value is 65 nm. The thickness can be applied to the full-band adjustment of a light output of the light emitting unit 110.

The thickness of the first sub-adjusting layer 1211 is D1, and the refractive index of the first sub-regulatory layer 1211 is N1, wherein D1=P1*N1+Q1, 0≤P1≤100 and −120≤Q1≤221 are satisfied. The thickness of the second sub-adjusting layer 1212 is D2, and the refractive index of the second sub-adjusting layer 1212 is N2, wherein D2=P2*N2+Q2, −100≤P2≤0 and 170≤Q2≤221 are satisfied.

In the above embodiment, the thickness of the first sub-adjusting layer 1211 can be set based on the refractive index of the first sub-adjusting layer 1211, and the thickness of the second sub-adjusting layer 1212 can be set based on the refractive index of the second sub-adjusting layer 1212, to achieve a good light adjusting effect. And when the optical film layer 13 is provided, the film thickness of the second sub-adjusting layer 1212 can be reduced and considered as the thickness of the optical film layer 13, so that the total thickness of the optical film layer 13 and the light adjusting layer 12 when the optical film layer 13 is provided is the same as the total thickness of the light adjusting layer without the optical film layer 13.

In a feasible embodiment, as shown in FIG. 6, the light adjusting layer 12 includes a plurality of light adjusting portions 120 arranged to be spaced apart from each other. The light adjusting portions 120 are located on a side of the light emitting unit 110 away from the substrate 10, and each light adjusting unit 120 corresponds to the light emitting unit 110 in one color.

In the above embodiment, the light adjusting layer 12 includes the plurality of light adjusting portions 120 arranged to be spaced apart from each other, each optical-adjusting portion is in one-to-one correspondence to one light-emitting unit 110. That is, the orthographic projection of the optical-adjusting portion on the substrate 10 covers the orthographic projection of the light-emitting unit 110 on the substrate 10. Alternatively, the orthographic projection of each optical-adjusting unit on the substrate 10 covers the orthographic projection of a plurality of light-emitting units 110 emitting the same color of light on the substrate 10. Specifically, it is only necessary to differentiate the design of the light adjusting portions 120 above the light emitting units 110 in different colors, in order to adjust the light emitting unit 110 in different colors separately and improve the adjusting effect on the light adjusting layer 12.

Specifically, two first adjusting layers 121 are provided. The two first adjusting layers 121 are formed as a first sub-adjusting layer 1211 and a second sub-adjusting layer 1212 arranged in a direction away from the substrate 10. One second adjusting layer 122 is provided, and the second-adjusting layer 122 is located between the first sub-adjusting layer 1211 and the second sub-adjusting layer 1212.

In a feasible embodiment, as shown in FIG. 7, when the display panel 1 further includes the encapsulation layer 14, the encapsulation layer 14 is located on a side of the light adjusting layer 12 away from the substrate 10 and in contact with the light adjusting layer 12.

A thickness of the second-adjusting layer 122 is a first fixed value. The first fixed value is 65 nm. This thickness can be applied to a full-band adjustment of a light output of the light-emitting unit 110.

The thickness of the first sub-adjusting layer 1211 is positively correlated with the refractive index of the first sub-adjusting layer 1211. The thickness of the first sub-adjusting layer 1211 is D1, wherein 15 nm≤D1≤40 nm is satisfied. The thickness of the first sub-adjusting layer 1211 does not vary with a wavelength of the light emitted by the light emitting unit 110 it covers.

A thickness of the second sub-adjusting layer 1212 is D2, and a wavelength of the light emitted by the light emitting unit 110 set opposite to the second sub-adjusting layer 1212 in the thickness direction of the substrate 10 is W, wherein D2=M*W2+V*W+S,−0.009≤M≤−0.003, 3.7≤V≤9.0 and −2240≤S≤−740 are satisfied. The thickness of the second sub-adjusting layer 1212 varies with the wavelength of the light emitted by the light emitting unit 110 it covers, allowing for a design of the thickness of the second sub-adjusting layer 1212 for different light emitting units 110 to achieve better control effects.

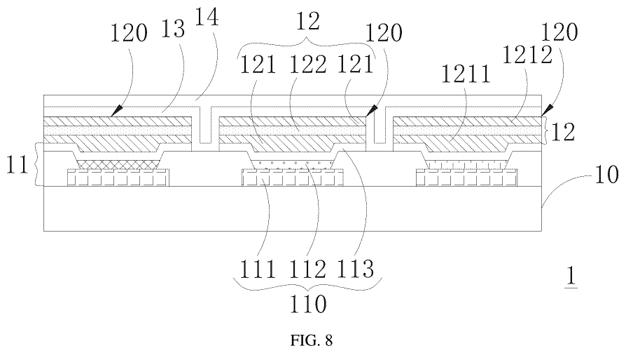

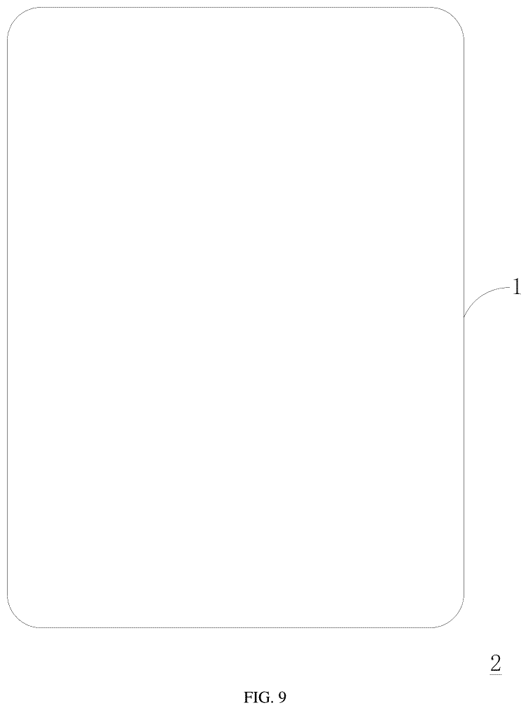

Alternatively, as shown in FIG. 8, when the display panel 1 further includes the optical film layer 13 and the encapsulation layer 14, the optical film layer 13 is located on the side of the light adjusting layer away from the substrate 10 and in contact with the light adjusting layer, and the encapsulation layer 14 is located on the side of the optical film layer 13 away from the substrate 10:

A thickness of the second adjusting layer 122 is a first fixed value. The first fixed value is 6 5nm. This thickness can be applied for a full-band adjustment of the light output of the light-emitting unit 110.

The thickness of the first sub-adjusting layer 1211 is positively correlated with the refractive index of the first sub-adjusting layer 1211. A thickness of the first sub-adjusting layer 1211 is D1, wherein 15 nm≤D1≤40 nm is satisfied. The thickness of the first sub-adjusting layer 1211 does not vary with the wavelength of the light emitted by the light emitting unit 110 it covers.

The thickness of the second sub-adjusting layer 1212 is D2, and the wavelength of the light emitted by the light emitting unit 110 set opposite to the second sub-adjusting layer 1212 in the thickness direction of the substrate 10 is W, wherein D2=M*W²+V*W+S, −0.009≤M≤−0.003, 3.7≤V≤9.0 and −2300 ≤S≤−800 are satisfied. The thickness of the second sub-adjusting layer 1212 varies with the wavelength of the light emitted by the light emitting unit 110 it covers, allowing for a design of the thickness of the second sub-adjusting layer 1212 for different light emitting units 110 to achieve better control effects. In this case, since the display panel 1 also includes the optical film layer 13, both the optical film layer 13 and the second sub-adjusting layer 1212 are formed as film layers above the second control layer 122 with lower refractive index, thereby reducing the film thickness of the second sub-adjusting layer 1212. Further, a thinning amount of the film layer of the second sub-adjusting layer 1212 can be considered as the thickness of the optical film layer 13, so that the total thickness of the optical film layer 13 and the light adjusting layer 12 when the optical film layer 13 is provided is the same as the total thickness of the light adjusting layer 12 without the optical film layer 13. Specifically, the thickness of the optical film layer 13 can be 60 nm.

In a feasible embodiment, the plurality of light emitting units 110 include a first light-emitting unit 110, a second light-emitting unit 110, and a third light emitting unit 110; A wavelength of the light emitted by the first light emitting unit 110 is 460 nm, a wavelength of the light emitted by the second light emitting unit 110 is 530 nm, and a wavelength of the light emitted by the third light emitting unit 110 is 620 nm.

Specifically, the first light emitting unit 110 is a blue light emitting unit 110, the second light emitting unit 110 is a green light emitting unit 110, and the third emitting unit 110 is a red light emitting unit 110.

In the above embodiment, the light emitting layer 11 includes light emitting units 110 in three colors, specifically the first light emitting unit 110, the second light emitting unit 110, and the third light emitting unit 110. The light emitting layer 11 may also include the light emitting units 110 in more colors, which is not particularly limited thereto in the present disclosure. The present disclosure only provides an example of the display panel 1 with the light emitting units 110 in three colors.

In this case, the plurality of light adjusting portions 120 include a first light adjusting portion 120, a second light adjusting portion 120, and a third light adjusting portion 120 that are spaced apart from each other. The first light adjusting portion 120 is located on a side of the first light emitting unit 110 away from the substrate 10, the second light adjusting portion 120 is located on a side of the second light emitting unit 110 away from the substrate 10, and the third light adjusting portion 120 is located on a side of the third light emitting unit 110 away from the substrate 10.

Specifically, the orthographic projection of the first light adjusting portion 120 on the substrate 10 may cover the orthographic projection of one first light emitting unit 110 on the substrate 10. Or, the orthographic projection of the first light adjusting portion 120 on the substrate 10 may cover the orthographic projection of multiple first light emitting units 110 on the substrate 10. The orthographic projection of the second light adjusting portion 120 on the substrate 10 can cover the orthographic projection of one second light emitting unit 110 on the substrate 10, or the orthographic projection of the second light adjusting unit 120 on the substrate 10 can cover the orthographic projection of multiple second light emitting units 110 on the substrate 10. The orthographic projection of the third light adjusting unit 120 on the substrate 10 can cover the orthographic projection of one third light emitting unit 110 on the substrate 10, or the orthographic projection of the third light regulating unit 120 on the substrate 10 can cover the orthographic projection of multiple third light-emitting units 110 on the substrate 10.

Specifically, when the display panel 1 further includes the encapsulation layer 14, the encapsulation layer 14 is located on the side of the light adjusting layer 12 away from the substrate 10 and in contact with the light adjusting layer 12.

The thickness of the second adjusting layer 122 is the first fixed value. The first fixed value is 65 nm. This thickness can be applied for a full-band adjustment of the light output of the light emitting unit 110.

The thickness of the first sub-adjusting layer 1211 is D1, the refractive index of the first sub-adjusting layer 1211 is N1, the thickness of the second sub-adjusting layer 1212 is D2, and the refractive index of the second sub-adjusting layer 1212 is N2.

For a part of the first sub-adjusting layer 1211 located within the first light adjusting portion 120, D1=100*N1−119 is satisfied, and for a part of the second sub-adjusting layer 1212 located within the first light adjusting portion 120, D2=−100*N2+281 is satisfied. For a part of the first sub-adjusting layer 1211 located within the second light adjusting portion 120, D1=100*N1−119 is satisfied, and for a part of the second sub-adjusting layer 1212 located within the second light adjusting portion 120: D2=(2*e⁻¹²) N2+161. For a part of the first sub-adjusting layer 1211 located within the third light adjusting portion 120, D1=100*N1−119 is satisfied, and for a part of the second sub-adjusting layer 1212 located within the third light adjusting portion 120, D2=−100*N2+131 is satisfied. When the wavelength of the light emitted by the first emitting unit 110 is 460 nm, the wavelength of the light emitted by the second emitting unit 110 is 530 nm, and the wavelength of the light emitted by the third emitting unit 110 is 620 nm, both the thickness of the part of the first sub-adjusting layer 1211 and the thickness of the part of the second sub-adjusting layer 1212 within each of the first light adjusting portion 120, the thickness of the part of the second light adjusting portion 120, and the third light adjusting portion 120 can be calculated according to the above formula. This enables differential design between the first light adjusting unit 120, the second light adjusting unit 120, and the third light adjusting unit 120 to adapt to different light emitting units emitting lights with different wavelengths, and adjusts the adaptability of different light emitting units 110 to improve the light output efficiency of each light emitting unit 110.

Alternatively, when the display panel 1 also includes the optical film layer 13 and the encapsulation layer 14, the optical film layer 13 is located on the side of the light adjusting layer away from the substrate 10 and in contact with the light adjusting layer, and the encapsulation layer 14 is located on the side of the optical film layer 13 away from the substrate 10.

The thickness of the second adjusting layer 122 is the first fixed value. The first fixed value is 65 nm. This thickness can be applied for a full-band adjustment of the light output of the light emitting unit 110.

The thickness of the first sub-adjusting layer 1211 is D1, the refractive index of the first sub-adjusting layer 1211 is N1, the thickness of the second sub-adjusting layer 1212 is D2, and the refractive index of the second sub-adjusting layer 1212 is N2. For the part of the first sub-adjusting layer 1211 located within the first light-adjusting portion 120, D1=100*N1−119 is satisfied, and for the part of the second sub-adjusting layer 1212 located within the portion within the first light regulatory portion 120, D2=−100*N2+221 is satisfied. For the part of the first sub-adjusting layer 1211 located within the second light adjusting portion 120, D1=100*N1−119 is satisfied, and for the part of the second sub-adjusting layer 1212 located within the second light adjusting portion 120, D2=(2*e⁻¹²) N2+101 is satisfied. For the part of first sub-adjusting layer 1211 located within the third light adjusting portion 120, D1=100*N1−119 is satisfied, and for the part of the second sub-adjusting layer 1212 located within the third light adjusting portion 120, D2=−100*N2+191 is satisfied. In this case, since the display panel 1 also includes the optical film layer 13, both the optical film layer 13 and the second sub-adjusting layer 1212 are formed as film layers above the second control layer 122 with lower refractive index, thereby reducing the film thickness of the second sub-adjusting layer 1212. Further, a thinning amount of the film layer of the second sub-adjusting layer 1212 can be considered as the thickness of the optical film layer 13, so that the total thickness of the optical film layer 13 and the light adjusting layer 12 when the optical film layer 13 is provided is the same as the total thickness of the light adjusting layer 12 without the optical film layer 13. Specifically, the thickness of the optical film layer 13 can be 60 nm.

In a feasible embodiment, when the display panel 1 includes the encapsulation layer 14, and the thickness of the light adjusting layer is D, wherein 120 nm≤D≤260 nm is satisfied. In the above embodiment, the thickness of the light adjusting layer can be 120 nm, 150 nm, 176 nm, 199 nm, 200 nm, 208 nm, 260 nm, etc., which is not specially limited thereto in the present disclosure.

Alternatively, the optical film layer 13 and the encapsulation layer 14 are provided, the optical film layer 13 is located on the side of the light adjusting layer away from the substrate 10 and in contact with the light adjusting layer. The encapsulation layer 14 is located on the side of the optical film layer 13 away from the substrate 10. The thickness of the light adjusting layer is D, and 60 nm≤D≤200 nm is satisfied.

In the above embodiment, the thickness of the light adjusting layer can be 60 nm, 89 nm, 98 nm, 130 nm, 156 nm, 199 nm, 200 nm, etc., which is not specially limited thereto in the present disclosure.

When the display panel 1 includes the optical film layer 13, the film thickness of the light adjusting layer can be reduced. Further, a thinning amount of the film layer of the light adjusting layer can be considered as the thickness of the optical film layer 13, so that the total thickness of the optical film layer 13 and the light adjusting layer 12 when the optical film layer 13 is provided is the same as the total thickness of the light adjusting layer 12 without the optical film layer 13. Specifically, the thickness of the first adjusting layer 121 of the light adjusting layer located at one end away from the substrate 10 can be reduced.

Specifically, the thickness of the optical film layer 13 can be 60 nm.

In a feasible embodiment, the first adjusting layer 121 includes multiple layers, with at least some of the layers having different refractive indices and all lower than the refractive index of the second adjusting layer 122. And/or, the second adjusting layer 122 includes multiple layers, with at least some of the layers having different refractive indices and all greater than the refractive index of the first adjusting layer 121.

Materials of the first adjusting layer 121 include a fluorine-containing organic compound, a polymer or a metal oxide; materials of the second adjusting layer 122 include fluorenes, spirofluorenes, or diazinecans.

Specifically, materials of the first adjusting layer 121 include an organic material.

Specifically, materials of the first adjusting layer 121 include molybdenum oxide or silicon dioxide.

In a feasible embodiment, the refractive index of the first adjusting layer 121 is N3, wherein 2.1≤N3≤2.2 is satisfied. The refractive index of the second adjusting layer 122 is N4, wherein 1.5≤N4≤1.6 is satisfied.

In the above embodiment, specifically, N3 can be 2.1, 2.15, 2.16, 2.18, 2.2, etc., which is not specially limited thereto in the present disclosure. Specifically, N4 can be 1.5, 1.52, 1.53, 1.56, 1.6, etc., which is not specially limited thereto in the present disclosure.

In the above embodiment, when the refractive index of the first adjusting layer 121 and the refractive index of the second adjusting layer 122 are within the above ranges respectively, the first adjusting layer 121 and the second adjusting layer 122 are stacked in the direction away from the substrate 10 to have a good adjusting effect on the light emitted by the light emitting unit 110, in order to improve the light output efficiency and reduce the power consumption of the display panel 1.

In the above embodiment, the display panel 1 includes the substrate 10, the light emitting layer 11, and the light adjusting layer 12. The substrate 10 is further provided with a driving circuit, which controls the light emitting layer 11 above to emit light. The encapsulation layer 14 is provided on the light adjusting layer 12, and a touch layer, a polarizer, and a cover plate are sequentially provided on the encapsulation layer 14.

The present disclosure also provides a display device 2, as shown in FIG. 9, and includes any of the display panels 1 provided in the above embodiments of the present disclosure.

The display device 2 can be a mobile terminal, such as a mobile phone or laptop, or a fixed terminal, such as a TV or computer monitor, or a wearable device, such as a watch, which is not specially limited thereto in the present disclosure.

According to the embodiments described in the present disclosure, these embodiments do not fully describe all the details, nor do they limit the present disclosure to specific embodiments. Obviously, based on the above description, many modifications and changes can be made. The description selects and specifically describes these embodiments in order to better explain the principles and practical applications of the present disclosure, so that those skilled in the art can make good use of the present disclosure and modifications based on the present disclosure. The present disclosure is only limited by the claims and all their scope and equivalents.

What is claimed is:

1. A display panel, comprising:
a substrate;
a light-emitting layer comprising a plurality of light-emitting units formed on a side of the substrate; and
a light adjusting layer arranged on a side of the light-emitting layer away from the substrate and comprising at least a first adjusting layer and at least a second adjusting layer, the first adjusting layer and the second adjusting layer being alternately stacked along a direction away from the substrate, a refractive index of the first adjusting layer being less than a refractive index of the second adjusting layer, and the first adjusting layer being arranged on each of an end of the light adjusting layer close to the substrate and an end of the light adjusting layer away from the substrate.

2. The display panel of claim 1, wherein an orthographic projection of the light adjusting layer on the substrate covers the substrate, the first adjusting layer is continuous in a direction parallel to the substrate, and the second adjusting layer is continuous in the direction parallel to the substrate.

3. The display panel of claim 2, wherein the at least a first adjusting layer comprises two first adjusting layers, the two first adjusting layers are configured as a first sub-adjusting layer and a second sub-adjusting layer arranged in a direction away from the substrate respectively, and one second adjusting layer is provided and located between the first sub-adjusting layer and the second sub-adjusting layer.

4. The display panel of claim 3, further comprising an encapsulation layer, wherein the encapsulation layer is located on a side of the light adjusting layer away from the substrate and is in contact with the light adjusting layer;
a thickness of the second adjusting layer is defined as a first fixed value;
a thickness of the first sub-adjusting layer is D1, and a refractive index of the first sub-adjusting layer is N1, wherein D1=P1*N1+Q1, 0≤P1≤100 and −120≤Q1≤221 are satisfied;
a thickness of the second sub-adjusting layer is D2, and a refractive index of the second sub-adjusting layer is N2, wherein D2=P2*N2+Q2, −100≤P2≤0 and −60≤Q2≤251 are satisfied.

5. The display panel of claim 3, further comprising an optical film layer and an encapsulation layer, wherein the optical film layer is located on a side of the light adjusting layer away from the substrate and is in contact with the light adjusting layer, and the encapsulation layer is located on a side of the optical film layer away from the substrate;
a thickness of the second adjusting layer is defined as a first fixed value;
a thickness of the first sub-adjusting layer is D1, and an refractive index of the first sub-adjusting layer is N1, wherein D1=P1*N1+Q1, 0≤P1≤100 and −120≤Q1≤221 are satisfied;
a thickness of the second sub-adjusting layer is D2, and a refractive index of the second sub-adjusting layer is N2, wherein D2=P2*N2+Q2, −100≤P2≤0 and 170≤Q2≤221 are satisfied.

6. The display panel of claim 1, wherein the light adjusting layer comprises a plurality of light adjusting portions arranged to be spaced apart from each other, the light adjusting portions are located on sides of the light-emitting units away from the substrate, and each light adjusting portion is correspondingly arranged for one light emitting unit in one color.

7. The display panel of claim 6, wherein the at least a first adjusting layer comprises two first adjusting layers and configured as a first sub-adjusting layer and a second sub-adjusting layer arranged in a direction away from the substrate, one second adjusting layer is provided and located between the first sub-adjusting layer and the second sub-adjusting layer.

8. The display panel of claim 6, further comprising an encapsulation layer, wherein the encapsulation layer is located on a side of the light adjusting layer away from the substrate and is in contact with the light adjusting layer;
a thickness of the second adjusting layer is defined as a first fixed value;
a thickness of the first sub-adjusting layer is positively correlated with a refractive index of the first sub-adjusting layer, and a thickness of the first sub-adjusting layer is D1, wherein 15 nm≤D1≤40 nm;
a thickness of the second sub-adjusting layer is D2, and a wavelength of a light emitted by the light-emitting unit opposite to the second sub-adjusting layer along a thickness direction of the substrate is W, wherein D2=M*W²+V*W+S, −0.009≤M≤−0.003, 3.7≤V≤9.0 and −2240≤S≤−740 are satisfied.

9. The display panel of claim 6, wherein the display panel further comprises an optical film layer and an encapsulation layer are provided, the optical film layer is located on a side of the light adjusting layer away from the substrate and is in contact with the light adjusting layer, and the encapsulation layer is located on a side of the optical film layer away from the substrate;
a thickness of the second adjusting layer is defined as a first fixed value;
a thickness of the first sub-adjusting layer is positively correlated with a refractive index of the first sub-adjusting layer, and a thickness of the first sub-adjusting layer is D1, wherein 15 nm≤D1≤40 nm is satisfied;
a thickness of the second sub-adjusting layer is D2, and a wavelength of a light emitted by the light-emitting unit opposite to the second sub-adjusting layer along a thickness direction of the substrate is W, wherein D2=M*W²+V*W+S, −0.009≤M≤−0.003, 3.7≤V≤9.0 and −2300≤S≤−800 are satisfied.

10. The display panel of claim 6, wherein the plurality of light-emitting units comprise a first light-emitting unit, a second light-emitting unit and a third light-emitting unit, a wavelength of a light emitted by the first light-emitting unit is 460 nm, a wavelength of a light emitted by the second light-emitting unit is 530 nm, and a wavelength of a light emitted by the third light-emitting unit is 620 nm;
the plurality of light adjusting portions comprise a first light adjusting portion, a second light adjusting portion and a third light adjusting portion arranged to be spaced apart from each other, the first light adjusting portion is located on a side of the first light-emitting unit away from the substrate, the second light adjusting portion is located on a side of the second light-emitting unit away from the substrate, and the third light adjusting portion is located on a side of the third light-emitting unit away from the substrate.

11. The display panel of claim 10, further comprising an encapsulation layer, wherein the encapsulation is located on a side of the light adjusting layer away from the substrate and is in contact with the light adjusting layer;
a thickness of the second adjusting layer is defined as a first fixed value;
a thickness of the first sub-adjusting layer is D1, a refractive index of the first sub-adjusting layer is N1, a thickness of the second sub-adjusting layer is D2, and a refractive index of the second sub-adjusting layer is N2;
for a part of the first sub-adjusting layer located within the first light adjusting portion, D1=100*N1−119 is satisfied, and for a part of the second sub-adjusting layer located within the first light adjusting portion, D2=−100*N2+281 is satisfied;
for a part of the first sub-adjusting layer located within the second light adjusting portion, D1=100*N1−119 is satisfied, and for a part of the second sub-adjusting layer located within the second light adjusting portion, D2=(2*e⁻¹²) N2+161 is satisfied;
for a part of the first sub-adjusting layer located within the third light adjusting portion, D1=100*N1−119 is satisfied, and for a part of the second sub-adjusting layer located within the third light adjusting portion, D2=−100*N2+131 is satisfied.

12. The display panel of claim 10, further comprising an optical film layer and an encapsulation layer, wherein the optical film layer is located on a side of the light adjusting layer away from the substrate and is in contact with the light adjusting layer, and the encapsulation layer is located on a side of the optical film layer away from the substrate;
a thickness of the second adjusting layer is defined as a first fixed value;
a thickness of the first sub-adjusting layer is D1, a refractive index of the first sub-adjusting layer is N1, and a refractive index of the second sub-adjusting layer is N2;
for a part of the first sub-adjusting layer located within the first light adjusting portion, D1=100*N1−119 is satisfied, and for a part of the second sub-adjusting layer located within the first light adjusting portion, D2=−100*N2+221 is satisfied;
for a part of the first sub-adjusting layer located within the second light adjusting portion, D1=100*N1−119 is satisfied, and for a part of the second sub-adjusting layer located within the second light adjusting portion, D2=(2*e⁻¹²) N2+101 is satisfied; and
for a part of the first sub-adjusting layer located within the third light adjusting portion, D1=100*N1−119 is satisfied, for a part of the second sub-adjusting layer located within the third light adjusting portion, D2=−100*N2+191 is satisfied.

13. The display panel of claim 1, further comprising an encapsulation layer, wherein the encapsulation layer is located on a side of the light adjusting layer away from the substrate and is in contact with the light adjusting layer, and a thickness of the light adjusting layer is D, wherein 120 nm≤D≤260 nm is satisfied.

14. The display panel of claim 1, further comprising an optical film layer and an encapsulation layer, wherein the optical film layer is located on a side of the light adjusting layer away from the substrate and is in contact with the light adjusting layer, the encapsulation layer is located on a side of the optical film layer away from the substrate, and a thickness of the light adjusting layer is D, wherein 60 nm≤D≤200 nm is satisfied.

15. The display panel of claim 1, wherein the at least a first adjusting layer comprises multiple layers, and refractive indices of at least some of the layers are different and are smaller than the refractive index of the second adjusting layer.

16. The display panel of claim 1, wherein the at least a second adjusting layer comprises multiple layers, and refractive indices of at least some of the layers are different and are greater than the refractive index of the first adjusting layer.

17. The display panel of claim 15, wherein a material of the first adjusting layer comprises a fluorine-containing organic compound, a polymer or a metal oxide; and a material of the second adjusting layer comprises fluorenes, spirofluorenes, or diazinecans.

18. The display panel of claim 15, wherein a material of the first adjusting layer comprises molybdenum oxide or silicon dioxide.

19. The display panel of claim 1, wherein the refractive index of the first adjusting layer is N3, and 2.1≤N3≤2.2 is satisfied; the refractive index of the second adjusting layer is N4, and 1.5≤N4≤1.6 is satisfied.

20. A display device comprising the display panel of claim 1.
